(19) United States
(12) Patent Application Publication
(10) Pub. No.: US 2009/0119914 A1
(43) Pub. Date: May 14, 2009

(54) Process for Forming Electrical Contacts on a Semiconductor Wafer Using a Phase Changing Ink

(76) Inventors: Roger F. Clark, Frederick, MD (US); Timothy D. Koval, Union Bridge, MD (US)

Correspondence Address: CAROL WILSON;BP AMERICA INC., MAIL CODE 5 EAST, 4101 WINFIELD ROAD, WARRENVILLE, IL, 60555, US

(21) Appl. No.: 12/097,687

(22) PCT Filed: Dec. 21, 2006
(86) PCT No.: PCT/US06/62454

§ 371 Date: Jun. 16, 2008

Related U.S. Application Data
(60) Provisional application No. 60/754,048, filed on Dec. 27, 2005.

(51) Int. Cl. H05K 3/12; B41J 2/175

(52) U.S. Cl. 29/846; 347/88

(57) ABSTRACT

A process for forming electrical contacts or electrical conductors on a surface of a substrate comprising ink jet printing a phase-change electrically conducting or semi-conducting printing ink or, such a phase-change printing ink that becomes electrically conducting or semi-conducting after a post-printing treatment of the applied ink.

This application claims the benefit of U.S. Provisional Patent Application No. 60/754,048, filed on Dec. 27, 2005.

### BACKGROUND OF THE INVENTION

This invention relates to forming electrical contacts or conduits on a substrate surface such as the surface of a semiconductor wafer. More particularly, this invention relates to a new process for forming electrical contacts on semiconductor wafers used for the manufacture of photovoltaic cells. This invention relates to a now process for manufacturing electrical contacts or conduits on a semiconductor wafer that is versatile and efficient, and whereby such electrical contacts or conductors are formed on a semiconductor wafer using a printing ink, preferably comprising one or more of a micro- and nano-scale metal, semiconductor, or insulator, for example, a glass powder, where the ink is solid at room temperature, but preferably of a viscosity of no more than 50 centipoise (cP) at printing temperatures, and a heated ink jet printer. On further processing, the components of the printing ink can be transformed to electrically conducting or semiconducting circuitry. This invention is also an electrical contact or conduit that can be made by such process.

Photovoltaic devices convert light energy, particularly solar energy, into electrical energy. Photovoltaically generated electrical energy can be used for all the same purposes that electricity generated by batteries or electricity obtained from established electrical power grids can be used, but is a renewable form of electrical energy. One type of photovoltaic device is known as a photovoltaic module, also referred to as a solar module. These modules contain one or, more typically and preferably, a plurality of photovoltaic cells, also referred to as solar cells, positioned and scaled between a supersaturate sheet, such as a sheet of clear glass or clear polymeric material, and a back sheet, such as a sheet of polymeric material or metal plate.

Although photovoltaic cells can be fabricated from a variety of semiconductor materials, silicon is generally used because it is readily available at reasonable cost and because it has the proper balance of electrical, physical and chemical properties for use in fabricating photovoltaic cells. In a typical procedure for the manufacture of photovoltaic cells using silicon as the selected semiconductor material, the silicon is doped with a dopant of either positive or negative conductivity type, formed into either ingots of monocrystalline silicon, or cast into blocks or “bricks” of what the art refers to as multicrystalline silicon, and these ingots or blocks are cut into thin substrates, also referred to as wafers, by various slicing or sawing methods known in the art. However, these are not the only methods used to obtain suitable semiconductor wafers for the manufacture of photovoltaic cells.

The surface of the wafer intended to face incident light when the wafer is formed into a photovoltaic cell is referred to herein as the front face or front surface, and the surface of the wafer opposite the front face is referred to herein as the back face or back surface.

Using as an example a p-doped wafer, the wafer is exposed to a suitable n-dopant to form an emitter layer and a p-n junction. In one method, the n-doped layer or emitter layer is formed by first depositing the n-dopant onto the surface of the p-doped wafer using techniques commonly employed in the art such as chemical or physical deposition and, after such deposition, the n-dopant is driven into the surface of the silicon wafer to further diffuse the n-dopant into the wafer surface. This “drive-in” step is commonly accomplished by exposing the wafer to heat or other energy source. A p-n junction is thereby formed at the boundary region between the n-doped layer and the p-doped silicon wafer substrate. In another method, the exposure to the n-dopant and the heating to drive in the dopant can be accomplished at the same time.

In order to utilize the electrical potential generated by exposing the p-n junction to light energy, the photovoltaic cell is typically provided with a conductive front electrical contact and a conductive back electrical contact. Such contacts are typically made of or contain one or more highly conducting metals and are, therefore, typically opaque. An alternative is to use transparent or semi-transparent conducting oxides for the contacts, but the benefit of partial transparency is usually offset by decreased conductivity requiring more conducting area. Since the front contact is on the side of the photovoltaic cell facing the sun or other source of light energy, it is generally desirable for the front contact to take up the least amount of area of the front surface of the cell, that is provide the least amount of shading, as possible, yet still capture and conduct the charge carriers generated by the incident light interacting with the cell.

A number of methods have been developed in the art for applying contacts to monocrystalline and multicrystalline silicon wafers. A typical procedure to form front contacts is to screen print strips of conductive material using a paste and then firing the paste at an elevated temperature to form conductive contacts. Generally, such front contacts are formed as an open grid pattern on the wafer to maximize the area of wafer surface exposed to the sun yet function as an effective electrical contact. Another method is to form a buried contact. A buried front contact is made by scribing or cutting a pattern of scribes or grooves into the front surface of the wafer in an open grid pattern and thereafter filling the grooves with a conducting material such as a highly conducting metal. A laser can be used to form the grooves for the buried grid contact. One or more methods can be used to fill such grooves. For example, electro-chemical plating of conductive metals from an aqueous solution of metal salts can be used. Back contacts have been made by screen printing a coating of a paste containing a conductive material on the back of the wafer and firing the paste at an elevated temperature to form the contact. These methods and the paste compositions used to form the front and back contacts are well known to those of skill in the art of fabricating photovoltaic cells. Although these methods for forming front and back contacts are suitable, they involve the use of a paste which must be fired at an elevated temperature to remove any solvents or other organic materials contained within in order to form the finished contact, or they involve the use of electro-chemical plating solutions. The pastes are at times difficult to work with because the high viscosity requires a significant mechanical force to apply them to the surface of a relatively fragile photovoltaic cell. Electro-chemical plating solutions are also subject to spills and can be corrosive.

The art therefore needs a process for adding electrical contacts or electrical conductors to the surface of a substrate material such as a semiconductor wafer used for the manufacture of photovoltaic cells and where such process is efficient, versatile, non-invasive, and provides high print resolution to reduce front side shading. The present invention provides such process.

### SUMMARY OF THE INVENTION

This invention is a process for forming electrical contacts or electrical conductors on a surface such as a surface of a semiconductor wafer comprising ink jet printing a phase-change, electrically conducting, or semi-electrically conducting printing ink or precursor material, or such a phase-change printing ink that becomes electrically conducting or semi-conducting after a post-printing treatment, on the wafer. By phase-change, we mean a material that is substantially solid or of high viscosity at room temperature, but that is substantially liquid or of low viscosity, and preferably below 50 cP, at elevated temperatures, for example, temperatures above about 30° C., such as temperatures of about 50° C. to about 150° C. This invention is also an electrical contact or electrical conductor on a semiconductor wafer wherein the electrical contact or conductor or precursor material is applied by ink jet printing a phase-change, electrically conducting or semi-conducting printing ink, or such a phase-change printing ink that becomes electrically conducting or semi-conducting after a post-printing treatment. The wafers having such electrical contacts printed thereon can be used for manufacturing photovoltaic cell. By semiconducting, we mean, with respect to the printing ink, the set of materials that have conductivity greater than an insulator but typically less than a metal. The semiconducting printing ink material may also provide additional device structure to the photovoltaic cell by means of replacing or supplementing the p or n-type layer, producing additional device layers, rectifying contacts, junctions, or other light-active or electrically-active areas.

This invention is also an apparatus for printing electrical contact or electrical conduits on a surface such as a semiconductor wafer using a phase-change, electrically conducting or semiconducting printing ink, or such a phase-change printing ink that becomes electrically conducting or semi-conducting after a post-printing treatment.

### BRIEF DESCRIPTION OF THE DRAWING

FIG. 1 shows a front electrical contact on a semiconductor wafer made in accordance with the process of this invention.

FIG. 2 shows a schematic of a jet printing head in accordance with an embodiment of this invention for printing electrical contacts and electrical conduits in accordance with this invention. The jet print nozzles can be arranged so as to maximize the print quality and definition, print speed, and/or area coverage depending on the specific printing pattern required.

### DETAILED DESCRIPTION OF THE INVENTION

The invention will now be described using as an example an embodiment of the invention whereby a front electrical contact is applied to a p-doped silicon wafer used for the manufacture of a photovoltaic cell. However, it is to be understood that the invention is not limited thereby. The processes disclosed herein can be used to form electrical contacts or electrical conduits or electrical devices on any suitable substrate such as other semiconductor wafers. For example, it can be used for forming electrical contacts on semiconductor materials such as n-doped silicon wafers.

A silicon wafer useful in the process of this invention for preparing photovoltaic cells is typically in the form of a thin, flat shape. The silicon may comprise one or more additional materials, such as one or more semiconductor materials, for example germanium, if desired. Although boron is widely used as the first, p-type dopant, other p-type dopants, for example gallium or indium, will also suffice. Boron is the preferred p-type dopant. Combinations of such dopants are also suitable. Thus, the first dopant can comprise, for example, one or more of boron, gallium or indium, and preferably it comprises boron. Suitable wafers are typically obtained by slicing or sawing p-doped silicon ingots, such as ingots of monocrystalline silicon, to form monocrystalline wafers, such as Czochralski (Cz) or float zone (FZ) silicon wafers. Suitable wafers can also be made by slicing or sawing blocks of cast, p-doped multicrystalline silicon. Silicon wafers can also be pulled straight from molten silicon using processes such as Edge-defined Film-fed Growth technology (EFG) or similar techniques. Wafers made by slicing or sawing block or “bricks” of multicrystalline silicon are the preferred wafers used in the process of this invention. Although the wafers can be any shape, wafers are typically circular, square or pseudo-square in shape. By “pseudo-square” is meant a predominantly square shape usually with rounded corners. Thus, in general, the wafers useful in this invention are flat and thin wafers that are typically round, square or pseudo-square in shape. For example, a wafer useful in this invention can be about 50 microns thick to about 400 microns thick. Usually, however, the wafers can be about 100 to about 300 microns thick. If circular they can have a diameter of about 100 to about 400 millimeters, for example 102 to 178 millimeters. If square or pseudo square, they can have a width of about 100 millimeters to about 210 millimeters and where, for the pseudo-square wafers, the rounded corners can have a diameter of about 127 to about 178 millimeters. The wafers useful in the process of this invention can have a surface area of about 100 to about 250 square centimeters. The wafers doped with the first dopant that are useful in the process of this invention can have a resistivity of about 0.1 to about 10 ohm.cm, typically of about 0.5 to about 2.0 ohm.cm. Although the term wafer as used herein includes the wafers obtained by the methods described, particularly by the sawing or cutting of ingots or blocks of silicon, it is to be understood that the term wafer can also include any other suitable semiconductor substrates useful for preparing photovoltaic cells by the process of this invention.

The front surface of the wafer doped with the first dopant is preferably textured. Texturing generally increases the efficiency of the resulting photovoltaic cell by increasing light absorption. For example, the wafer can be suitably textured using chemical etching, plasma etching or mechanical scribing. A second dopant of conductivity opposite to the first dopant is applied to the wafer to produce a first layer on the front surface of the wafer having conductivity opposite to the first dopant. Such first layer is the so-called emitter layer. Its formation produces a p-n junction in the wafer. When using a p-doped wafer as in this description of the invention, the front of the wafer is doped with an n-dopant to form the emitter layer. This can be accomplished by depositing a suitable source of n-dopant onto the wafer, and then heating the wafer to “drive” the n-dopant into the surface of the wafer. Gaseous diffusion can be used to deposit the n-dopant onto the wafer surface; however, other methods can also be used, such as ion implantation, solid source diffusion, or other methods used in the art to create an n-doped layer and a p-n junction, preferably proximal to the wafer surface. Phosphorus is a preferred n-dopant, but one or more other suitable n-dopants can be used. For example, one or more of phosphorus, arsenic, or antimony can be used. If, for example, phosphorus is used as the dopant, it can be applied to the wafer using phosphorus oxychloride (POCl₃), or phosphorus containing pastes. For example, liquid POCl₃ can be used. In the process of this invention, one procedure is to add the n-dopant as phosphorus by subjecting the wafers to an atmosphere of phosphorus oxychloride and molecular oxygen at an elevated temperature of about 700° C. to about 850° C. to deposit a layer of a phosphorus glass on the wafer. Such glass layer can be about 5 to about 20 nanometers thick, more typically from about 10 to about 15 nanometers. The n-dopant is preferably applied to—and thus the emitter layer is preferably formed on—only the front surface of the wafer. This can conveniently be accomplished by placing two wafers back-to-back when they are exposed to the material for adding the n-dopant. Other methods for adding the n-dopant to only the front surface of the wafer can, however, be used, such as placing the wafers on a flat surface to shield the back surface of the wafer from being exposed to the dopant material. Other embodiments may allow n-dopant onto all or at least part of the back surface with subsequent compensation by, for example, an aluminum p-dopant introduced during the formation of a back surface field and electrical contact.

In a preferred embodiment of this invention, a surface coating, preferably one that can function as an anti-reflective coating, is deposited on the front surface of the wafer after formation of the emitter layer on the front surface. Such coating can be, for example, a layer of a dielectric such as tantalum oxide, silicon dioxide, titanium oxide, or silicon nitride, which can be added by methods known in the art, for example, plasma enhanced chemical vapor deposition (PECVD), low pressure chemical vapor deposition (LPCVD), thermal oxidation, screen printing of pastes, inks or sol gel, etc. Combinations of coatings can also be used. The preferred coating is an anti-reflective coating comprising silicon nitride. Preferably, in the process of this invention a silicon nitride layer is either applied using LPCVD or PECVD. A suitable method for applying the silicon nitride by LPCVD is to expose the wafer to an atmosphere of silicon compound, such as dichlorosilane, and ammonia at an elevated temperature of about 750° C. to about 850° C.

At the time of application, the surface coating deposited on the front surface of the wafer is preferably at least about 70 nanometers thick, and preferably less than about 140 nanometers. The surface coating can be, for example, about 110 to about 130 nanometers thick. The surface coating, preferably silicon nitride, on the finished photovoltaic cell can be about 70 to about 100 nanometers thick.

In accordance with an embodiment of a process of this invention, a front electrical contact is applied to the front surface of the wafer using a phase change, electrically conducting printing ink, or such a phase-change printing ink that becomes electrically conducting or semi-conducting after a post-printing treatment, and where the ink is applied using an ink jet printer. Ink compositions useful in the process of this invention can be selected from the compositions disclosed in U.S. Application U.S. 2004/0046154 A1, published on Mar. 11, 2004, incorporated herein by reference, provided they have the appropriate low viscosity at the temperature used for printing in accordance with the process of this invention and, preferably, do not readily plug the ejection orifices of the printing apparatus used for printing. Suitable electrically conducting printing inks can be prepared by combining one or more of the following materials from each of categories:

1. A phase-change vehicle, preferably of the class of low-melting point waxes, polymers, ionic liquids or other suitable materials, with melting point between the range of 0 and 150° C. The vehicle must demonstrate a change in viscosity from substantially a solid at ambient temperatures, for example, temperatures of about 10° C. to about 30° C. to substantially a liquid, preferably with liquid viscosity below 50 centipoise (cP) when melted. These can be of the hydrocarbon paraffins, alcohols, ethers, acids, esters or amines of suitable melting point and viscosity, such as hexadecyl ether (55° C.), 1-eicosanol (72° C.), or tricosane (47.6° C.).

2. A metal or semiconducting micro- or nano-scale powder, preferably of the group of metals, such as Al, Si, Ti, Cr, Co, Ni, Cu, Mo, Pd, Ag, Sn, W, Ir, Pt, or Au, or doped or un-doped semiconductors of Group 4, III-V, II-VI, I-III-V, or combinations of these. Powders can be obtained from several commercial sources such as Engelhard Corporation or many other electronics suppliers.

3. And optionally, an insulator or glass micro- or nano-scale powder to act as a flux for attachment of the metal contact to the photovoltaic cell. Its composition may comprise one or more of, but is not limited to, a metal and non-metal oxide, halide, sulfide, phosphide glasses. The flux may also comprise a reactive organic or inorganic molecule that would provide fluxing capabilities. Many such insulator or glass ceramic powders are commercially available through ceramic glaze and electronic materials manufacturers.

The components listed above are combined to provide for the desired viscosity at the printing temperature used, and the desired electrical conductivity after application and optional firing of the printed ink.

In addition, the electrically conducting inks used in the method of this invention include inks that are electrically conducting or semiconducting as applied, or become better electrical conductors, only after a treatment subsequent to being printed. For example, the electrically conducting inks can be in the form of a precursor material that, after printing, is heated or otherwise cured or treated to make it electrically conducting or to enhance its electrical conductivity.

The solid electrically conducting ink is applied to the wafer using an ink jet printer designed to print phase-change inks. Such ink jet printers, particularly the print heads from such printers, are available from Xerox Corporation. Such printers can be programmed, adjusted or set-up to print a desired pattern of the solid, electrically conducting printing ink on the semiconductor wafer, such as a wafer used for the manufacture of a photovoltaic cell. In one process for printing such patterns, the solid, electrically conducting printing ink is heated within the print head to a temperature above its melting temperature, for example, a temperature of about 50° C. to about 150° C., and dispensed by the ink jet print head in accordance in the desired pattern for the front electrical contact. In the preferred process, the wafer is at a temperature lower than the melting temperature of the printing ink so that after the ink is dispensed from the ink jet printer it rapidly cools and solidifies on the wafer surface. As mentioned, after the electrically conduction ink or ink precursor is printed on the wafer in the desired pattern, the wafer can be fired, that is heated, to an elevated temperature, for example, a temperature of about 300° C. to about 800° C. in air in order to cure the ink.

The pattern for the front electrical contact can be any desired pattern. One preferred pattern that can be used for square or “pseudo-square” shaped wafers, is a plurality of thin, spaced, parallel “finger” electrical contact lines across the surface of the wafer extending from one edge or close to the edge of the wafer, to the opposite edge or close to the opposite edge of the wafer. The first finger line is located close to an edge of the wafer and the last finger line in the plurality of finger lines is located close to the opposite edge of the wafer. Thus, the plurality of parallel finger lines run from one edge of the wafer to the opposite edge, and are parallel to the other edges of the square shaped (or pseudo-square shaped) wafer. The finger lines are connected by one, two or more spaced bus bar lines positioned perpendicular to the finger lines. The bus bar lines are generally wider than the finger lines. The bus bar lines serve to electrically connect the finger lines so that an electrical connection to the bus bars is an electrical connection to all the finger lines. For example, there can be about 30 to about 150 finger lines, with each line spaced from an adjacent line by about 1 mm to about 5 mm (center-to-center). Each such finger line can be about 50 μm to about 200 μm in width. The bus bar lines can be about 80 μm to about 3000 μm in width and are generally placed on the wafer surface so that the distance an electric charge has to travel on the finger lines is minimized. For example, if two bus bars are used, each would be placed, with respect to two opposite edges of the wafer, one quarter of the width of the wafer in from the respective edge of the wafer.

A desired pattern for the front contact, for example, finger lines and bus bar lines, can be printed in one pass of the printer over the wafer (or pass of the wafer under the printer) or it can be accomplished using multiple passes such as, for example, forming the finger lines first and then the bus bar lines. Additionally, one or more patterns for the front contact can be programmed into a computer that controls the printer so that at any time the printing pattern can be readily and quickly changed. This may be desirable, for example, where the production line is used to manufacture more than one type of photovoltaic cell. Thus, the process of this invention is very versatile in that it can provide for a plurality of different electrical contact designs. Since the print head design can be digitally controlled, multiple customizations of print patterns can be made, as well as maintaining print quality for veined or dendritic patterns without worrying about screen or screen printing artifacts such as mesh or squeegee directions.

Photovoltaic cells also generally have a back electrical contact on the back surface of the cell. Since the back surface of the cell does not face the sun, the back contact can and preferably does cover the entire or essentially the entire back surface of the cell. In accordance with this invention, the phase-change electrically conducting ink can be printed on the back surface of the wafer to form the back contact. Also in accordance with this invention, several different inks may be applied at once to the back surface to effect a single-side contact arrangement.

Although this invention has been described with respect to forming electrical contacts on a silicon wafer used for a photovoltaic cell, it is to be understood that the invention is not so limited. The method of this invention can be use to form electrical contact or electrical conductors on any surface, including the surface of a semiconductor used for other purposes such as semiconductors used in the industry for manufacturing electronic chips. With multiple ink print heads, such as those available from Xerox Corporation, it is possible to print multiple inks in a single pass. This modification allows for construction of multiple compositions of conducting lines on a single surface, such as those required for back contact solar cells.

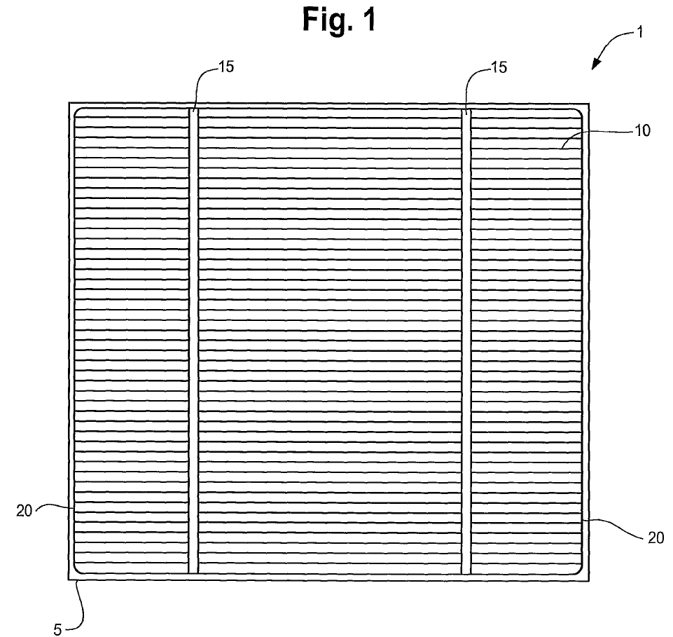

FIG. 1 shows a view of a photovoltaic cell 1 viewed looking at the light receiving, front surface of the photovoltaic cell. Photovoltaic cell 1 has silicon wafer 5. On silicon wafer 5 is printed finger lines 10. (there are a plurality of finger lines 10 shown in the figure but only one is labeled for clarity) and two bus bar lines 15. In addition, cell 20 has outer connecting lines 20 connecting the finger lines. Outer connecting lines 20 can have the same width as the finger lines. The combination of finger lines, bus bar lines and outer connecting line for the front electrical contact form the “open-grid” pattern for the photovoltaic cell. Each finger line 10, each outer connecting line, and each bus bar line are, in accordance with this invention, printed on the surface of wafer 5 using a ink jet printing using a phase-change electrically conducting printing ink. The different lines can be printed in stages by passing the wafer through the printer (or passing the printer over the wafer) multiple times, or the entire front contact can be printed in one such pass of the printer over the wafer or the wafer through the printer. FIG. 1 shows only one pattern for the front electrical contact printed on the wafer in accordance with this invention. However it is to be understood that any suitable pattern can be printed on the wafer.

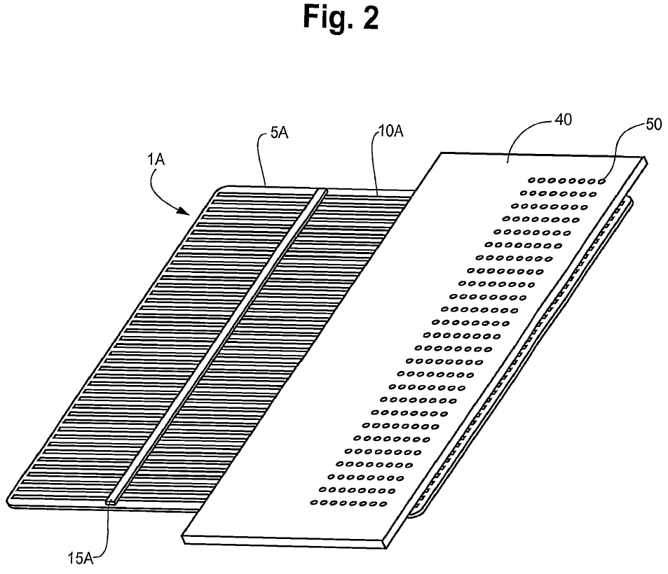

FIG. 2 shows a print head apparatus 40 suitable for practicing the process of this invention. As shown in FIG. 2, print head 40 has a plurality of holes or openings (orifices) 50 (for clarity, only one such hole is numbered) through which molten phase-change, electrically conducting printing ink passes. FIG. 2 also shows photovoltaic cell 1A where wafer 5A is being printed with finger lines 10A and bus bar 15A. The molten phase-change, electrically conducting printing ink is forced or passes through holes 50 an onto the wafer in order to form the desired pattern on the wafer, such as the pattern of lines 10A and bus bar 15 A as shown.

Only certain embodiments of the invention have been set forth and alternative embodiments and various modifications will be apparent from the above description to those of skill in the art. These and other alternatives are considered equivalents and within the spirit and scope of the invention.

U.S. Provisional Patent Application No. 60/754,048, filed on Dec. 27, 2005, is incorporated herein by reference in its entirety.

Having described the invention, that which is claimed is:

1. A process for forming electrical contacts or electrical conductors on a surface of a substrate comprising ink jet printing a phase-change electrically conducting or semi-conducting printing ink or, such a phase-change printing ink that becomes electrically conducting or semi-conducting after a post-printing treatment, on the surface.

2. The process of claim 1 wherein the substrate comprises a semiconductor material.

3. The process of claim 2 wherein the substrate is a semiconductor wafer used for the manufacture of a photovoltaic cell.

4. The process of claim 1 wherein the solid electrically conducting printing ink is heated in an ink jet printing apparatus to form melted ink, printing the melted ink on the substrate in a desired pattern, and cooling the ink to form the electrical contact or electrical conductor.

5. The process of claim 3 wherein the printing apparatus and ink compositions can be arranged and controlled to deposit multiple inks simultaneously, facilitating a high-throughput all rear side contacting method.

6. An electrical contact made by the process of claim 1.

7. An electrical conductor made by the process of claim 1.

8. A phase-change printing ink comprising: a phase-change vehicle having a melting point of about 0° C. to about 150° C.; one or more of a metal, semiconducting micro- or nano-scale powder; and, optionally, one or more of an insulator powder or glass micro- or nano-scale powder, wherein the composition is solid at room temperature and has a viscosity below about 50 cP at a temperature above about 30° C.

9. The ink of claim 8 wherein the phase-change vehicle is one or more of a wax, polymer, ionic liquid paraffin, alcohol, ether, acids, ester or amine having a melting point in the range of about 0° C. to about 150° C.

10. The ink of claim 9 wherein the metal or semiconducting micro- or nano-scale powder is selected from one or more of Al, Si, Ti, Cr, Co, Ni, Cu, Mo, Pd, Ag, Sn, W, Ir, Pt, Au, or doped or un-doped semiconductors of Group III-VI.
